(19) United States
(12) Patent Application Publication
(10) Pub. No.: US 2010/0019393 A1
(43) Pub. Date: Jan. 28, 2010

(54) PACKAGING STRUCTURE FOR INTEGRATION OF MICROELECTRONICS AND MEMS DEVICES BY 3D STACKING AND METHOD FOR MANUFACTURING THE SAME

(75) Inventors: Yu-Sheng HSIEH, Taiwan (TW); Jing-Yuan LIN, Tucheng City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: INDUSTRIAL TECHNOLOGY RESEARCH INSTITUTE, Taiwan (TW)

(21) Appl. No.: 12/197,519

(22) Filed: Aug. 25, 2008

(30) Foreign Application Priority Data
Jul. 23, 2008 (TW) 097127924

(51) Int. Cl. H01L 23/52; B23C 1/00

(52) U.S. Cl. 257/777; 29/592.1; 257/E23.141

(57) ABSTRACT

A packaging structure for integration of microelectronics and MEMS devices by 3D stacking is disclosed, which comprises: an ASIC unit, comprising a first substrate and a circuit layout formed on a surface of the first substrate, wherein a cavity is formed on the other surface and at least a through hole is formed on the ASIC unit; and a MEMS unit, comprising a second substrate and a micro sensor disposed on the second substrate; wherein the micro sensor is disposed in the cavity and there is a conductive material filling the through hole so that the ASIC unit and the MEMS unit can be electrically connected to each other when the ASIC unit is attached onto the MEMS unit.

### BACKGROUND OF THE INVENTION

1. Field of the Invention

The present invention generally relates to a packaging structure and a method for manufacturing the same and, more particularly, to a packaging structure for integration of microelectronics and MEMS devices by three-dimensional (3D) stacking and a method for manufacturing the packaging structure.

2. Description of the Prior Art

With the development in mobile communication and personal audio/video devices, the functionality thereof is significantly enhanced. For example, if one wants to be provided with photographing, audio/video entertainment, personal information management, navigation and communication services, he/she only has to bring with him/her a smart phone, instead of preparing a camera, a walkman, a personal digital assistant (PDA), a global positioning system (GPS), and a mobile phone. Therefore, the personal/portable electronic devices are made to be lighter, thinner, smaller and more powerful. In recent years, the development in the micro electromechanical system (MEMS) devices has made great progress. For example, the microphone and the accelerometer can be used and integrated in the handset. It is believed that, in the future, the RF MEMS-based devices and the micro-gyroscope will be integrated in the handset to enhance the functionality of the handset. In order to achieve the foregoing objects, it is thus a key issue to integrate the application specific integrated circuit (ASIC) devices and the MEMS devices with smaller, thinner, and more effective and inexpensive packaging technology.

The conventional MEMS device is not “smart”, which indicates that the conventional MEMS device is provided with only a sensor portion without amplification, reading and logic operation. Therefore, to manufacture a smart MEMS device, it requires at least an ASIC to be integrated with.

Moreover, since the MEMS device often comprises at least a sensitive and fragile microstructure such as a sensor film (such as an air sensor, or a bio-sensor) or a three-dimensional (3D) structure (such as a microphone, a micro accelerometer, a pressure sensor and a micro-gyroscope), proper assembly is required to protect the sensitive and fragile microstructure.

In the prior art, the MEMS device and the ASIC device are integrated in a hybrid manner in a packaging structure, for example, in U.S. Pat. No. 6,809,412 and U.S. Pat. No. 6,781,231. Moreover, in U.S. Pat. No. 6,452,238, a cap with a hollow portion is made to cover the MEMS device. The hollow portion serves as a cavity to accommodate the microstructure on the MEMS device.

Please refer to FIG. 1, which is a cross-sectional view of a conventional stacked structure of an ASIC unit and a MEMS unit. The stacked structure comprises an ASIC unit 10, a cap 11 and a MEMS unit 12. The ASIC unit 10 is stacked on the cap 11, which is further stacked on the MEMS unit 12. The ASIC unit 10 comprises a substrate 100 and a circuit layout 102 disposed on the substrate 100. The cap 11 is provided with a cavity 114. The MEMS unit 12 comprises a substrate 120 and a micro sensor 122 disposed on a surface of the substrate 120. The micro sensor 122 is disposed in the cavity 114. The ASIC unit 10 is provided with plurality of through holes 106, which are filled with a conductive material 108 when the ASIC unit 10 is attached onto the MEMS unit 12. The cap 11 is also provided with a plurality of through holes 110, which are filled with a conductive material 112. The ASIC unit 10 and the MEMS unit 12 are electrically connected to each other via the through holes 106 filled with the conductive material 108 and through holes 110 filled with the conductive material 112.

However, the cap in the above-mentioned packaging only provides protection. Therefore, some additional space is required on the MEMS unit for electrical connection between the MEMS unit and the ASIC unit or other circuit units. As a result, it is impossible to make the MEMS unit smaller. Moreover, the MEMS unit and the ASIC unit have to be packaged in a hybrid manner, which leads to energy consumption as well as undesirable noise. Since the packaging is two-dimensional, the size cannot be further minimized.

Moreover, in U.S. Pat. No. 7,061,099 filed by Intel, a cap is provided with a hollow portion and an electrical channel through the cap so that the cap is capable of protecting and connecting the MEMS unit to minimize the size of the packaging structure. However, the method for packaging and electrically connecting the MEMS unit and the ASIC unit by stacking is not presented.

Therefore, there is need in providing a packaging structure for integration of microelectronics and MEMS devices by three-dimensional (3D) stacking and a method for manufacturing the packaging structure.

### SUMMARY OF THE INVENTION

It is one object of the present invention to provide a packaging structure for integration of microelectronics and MEMS devices by three-dimensional (3D) stacking and a method for manufacturing the packaging structure. In the present invention, a cavity is provided in a surface of a substrate so that a micro sensor is disposed in the cavity when an ASIC unit is stacked with a MEMS unit.

In order to achieve the foregoing object, the present invention provides a packaging structure for integration of microelectronics and MEMS devices by 3D stacking, the packaging structure comprising: an ASIC unit, comprising a first substrate and a circuit layout formed on a surface of the first substrate, wherein a cavity is formed on the other surface and at least a through hole is formed on the ASIC unit; and a MEMS unit, comprising a second substrate and a micro sensor disposed on the second substrate; wherein the micro sensor is disposed in the cavity and there is a conductive material filling the through hole so that the ASIC unit and the MEMS unit are electrically connected to each other when the ASIC unit is attached onto the MEMS unit.

In order to achieve the foregoing object, the present invention further provides a method for manufacturing a packaging structure for integration of microelectronics and MEMS devices by 3D stacking, the method comprising steps of:
(a) providing an ASIC unit and a MEMS unit, the ASIC unit comprising a first substrate and a circuit layout formed on a surface of the first substrate and the MEMS unit comprising a second substrate and a micro sensor disposed on the second substrate;
(b) performing a thinning process on the other surface of the first substrate;
(c) forming a cavity on the other surface of the first substrate, wherein the micro sensor is disposed in the cavity;
(d) providing a conductive portion in the cavity, the conductive portion being electrically connected to the MEMS unit;
(e) stacking the ASIC unit and MEMS unit so that the micro sensor is disposed in the cavity;
(f) forming at least a through hole so that the through hole is electrically connected to the circuit layout and the conductive portion, respectively; and
(g) filling the through hole with a conductive material so that the circuit layout and the conductive portion are electrically connected.

### BRIEF DESCRIPTION OF THE DRAWINGS

The objects, spirits and advantages of the preferred embodiments of the present invention will be readily understood by the accompanying drawings and detailed descriptions, wherein:

FIG. 1 is a cross-sectional view of a conventional stacked structure of an ASIC unit and a MEMS unit;

FIG. 2 is a cross-sectional view of a packaging structure for integration of microelectronics and MEMS devices by three-dimensional (3D) stacking according to the present invention;

FIG. 3 is a cross-sectional view of a packaging structure for integration of microelectronics and MEMS devices by three-dimensional (3D) stacking according to another embodiment of the present invention;

FIG. 4 is a cross-sectional view of a packaging structure for integration of microelectronics and MEMS devices by three-dimensional (3D) stacking according to still another embodiment of the present invention; and

FIG. 5A to FIG. 5G are cross-sectional views showing a method for manufacturing a packaging structure for integration of microelectronics and MEMS devices by three-dimensional (3D) stacking according to still another embodiment of the present invention;

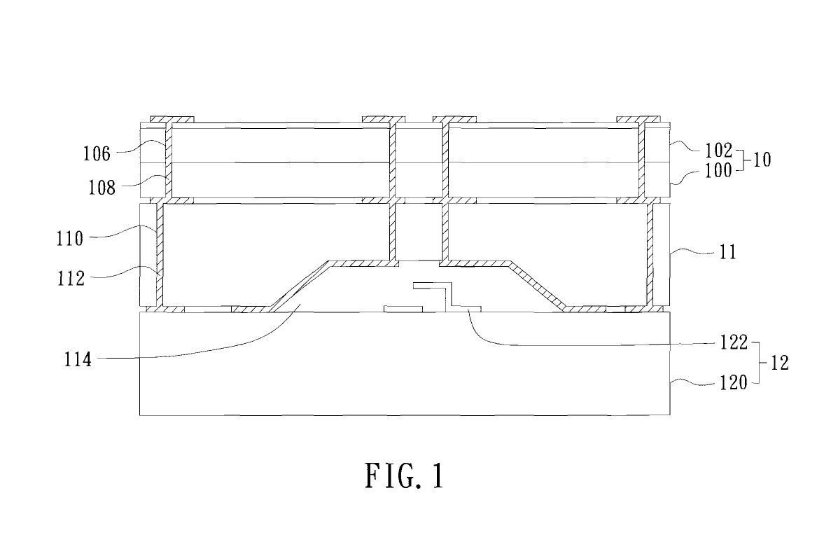

### DETAILED DESCRIPTION OF THE PREFERRED EMBODIMENT

The present invention can be exemplified by the preferred embodiments as described hereinafter.

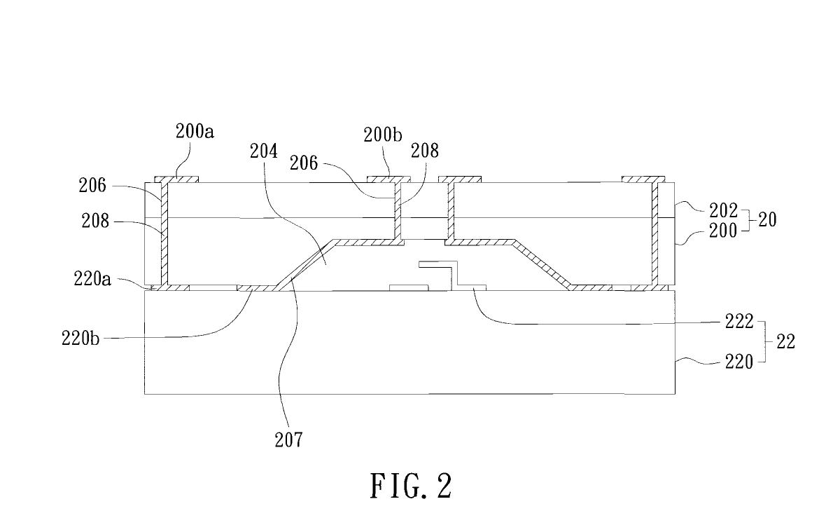

Please refer to FIG. 2, which is a cross-sectional view of a packaging structure for integration of microelectronics and MEMS devices by three-dimensional (3D) stacking according to the present invention. In FIG. 2, the packaging structure comprises an ASIC unit 20 and a MEMS unit 22. The ASIC unit 20 is stacked on the MEMS unit 22. The ASIC unit 20 comprises a substrate 200 and a circuit layout 202 disposed on a surface of the substrate 200. To achieve electrical connection, the ASIC unit 20 comprises a plurality of through holes 206 and the through holes 206 are filled with a conductive material 208, which can be a metal material such as copper (Cu). The MEMS unit 22 comprises a substrate 220 and a micro sensor 222 disposed on a surface of the substrate 220. However, the present invention is different from the prior art in that a cavity 204 is provided on a surface of the substrate 200 whereon the there is no circuit layout 202. Therefore, the micro sensor 222 is disposed in the cavity 204 when the ASIC unit 20 and the MEMS unit 22 are stacked. The through holes 206 are filled with the conductive material 208 so that an electrical connection portion 200a on the substrate 200 is electrically connected to an electrical connection portion 220a on the substrate 220. Similarly, an electrical connection portion 200b on the substrate 200 is electrically connected to an electrical connection portion 220b on the substrate 220 via the conductive material 208 filling the through holes 206 and a conductive portion 207 disposed in the cavity 204. Therefore, the circuit layout 202 of the ASIC unit 20 is electrically connected to the MEMS unit 22. Correspondingly, the ASIC unit 20 is electrically connected to the MEMS unit 22.

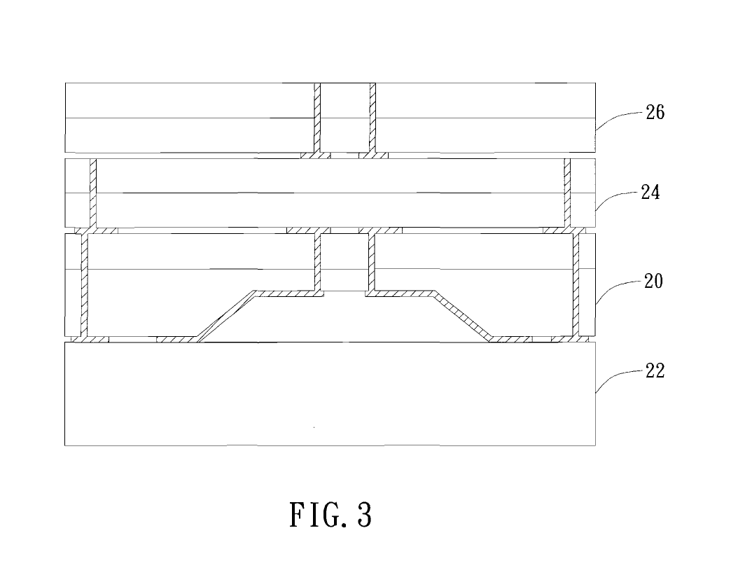

Please further refer to FIG. 3, which is a cross-sectional view of a packaging structure for integration of microelectronics and MEMS devices by three-dimensional (3D) stacking according to another embodiment of the present invention. In FIG. 3, an ASIC unit 24 and an ASIC unit 26 are further stacked on the 3D stacked structure (comprising the ASIC unit 20 and the MEMS unit 22) in FIG. 2. In other words, the ASIC unit 24 is stacked on the ASIC unit 20 and is provided with through holes filled with a conductive material to achieve electrical connection. The ASIC unit 26 is stacked on the ASIC unit 24 and is provided with through holes filled with a conductive material to achieve electrical connection. In the present embodiment, the present invention achieves multi-layered stacking and reduced layers.

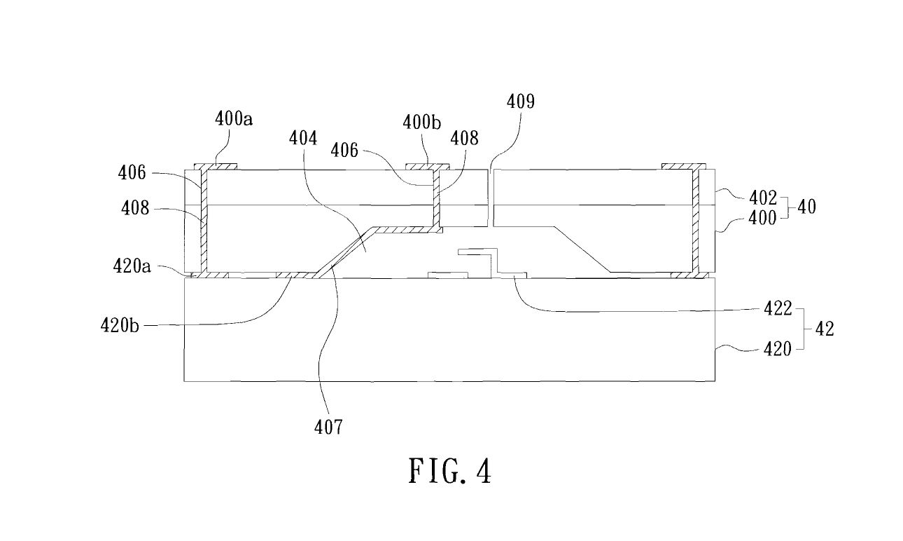

FIG. 4 is a cross-sectional view of a packaging structure for integration of microelectronics and MEMS devices by three-dimensional (3D) stacking according to still another embodiment of the present invention. The packaging structure comprises an ASIC unit 40 and a MEMS unit 42. The ASIC unit 40 is stacked on the MEMS unit 42. The ASIC unit 40 comprises a substrate 400 and circuit layout 402 disposed on a surface of the substrate 400. To achieve electrical connection, the ASIC unit 40 comprises a plurality of through holes 406 and the through holes 406 are filled with a conductive material 408, which can be a metal material such as copper (Cu). The MEMS unit 42 comprises a substrate 420 and a micro sensor 422 disposed on the substrate 420.

Similar to FIG. 2, the substrate 400 in FIG. 4 is provided with a cavity 404 on a surface whereon there is no circuit layout 402. Therefore, as the ASIC unit 40 and MEMS unit 42 are stacked, the micro sensor 422 is disposed in the cavity 40. The through holes 406 are filled with the conductive material 408 so that an electrical connection portion 400a on the substrate 400 is electrically connected to an electrical connection portion 420a on the substrate 420. Similarly, an electrical connection portion 400b on the substrate 400 is electrically connected to an electrical connection portion 420b on the substrate 420 via the conductive material 408 filling the through holes 406 and a conductive portion 407 disposed in the cavity 404. Therefore, the circuit layout 402 of the ASIC unit 40 is electrically connected to the MEMS unit 42. Correspondingly, the ASIC unit 40 is electrically connected to the MEMS unit 42.

The present embodiment is different from the previous embodiments in that the MEMS unit 12 in the present embodiment interacts with external signals (for example, sonic signals via the micro sensor 422). Therefore, a through hole 409 in the ASIC unit 40 is hollow without being filled with any conductive material and is stacked with the MEMS unit 42. As a result, the MEMS unit 42 is capable of sensing external signals such as sonic signals.

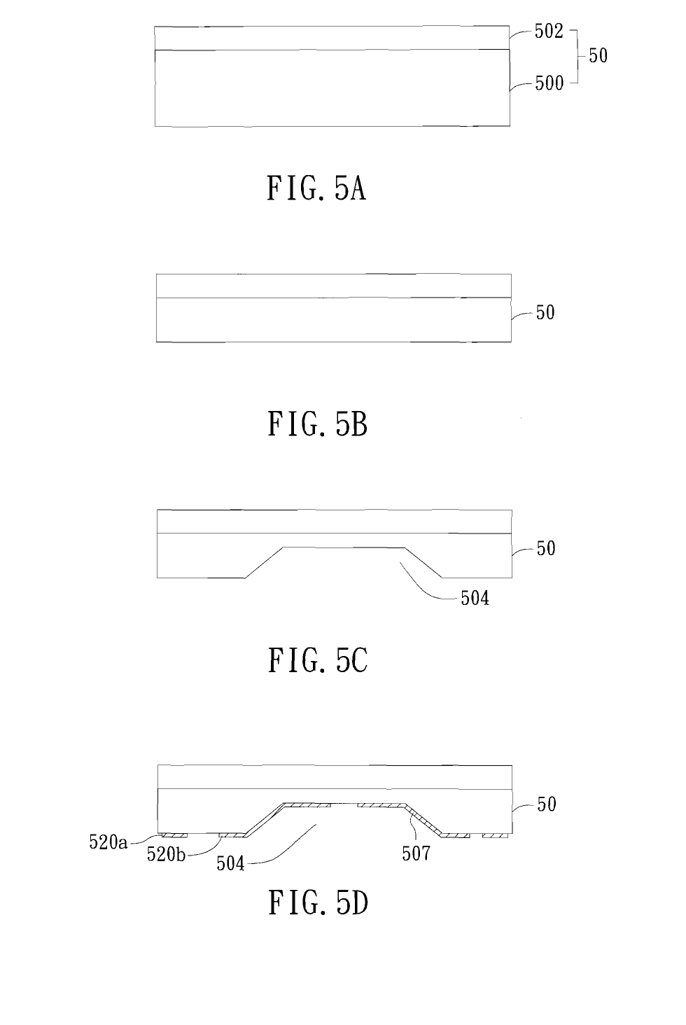

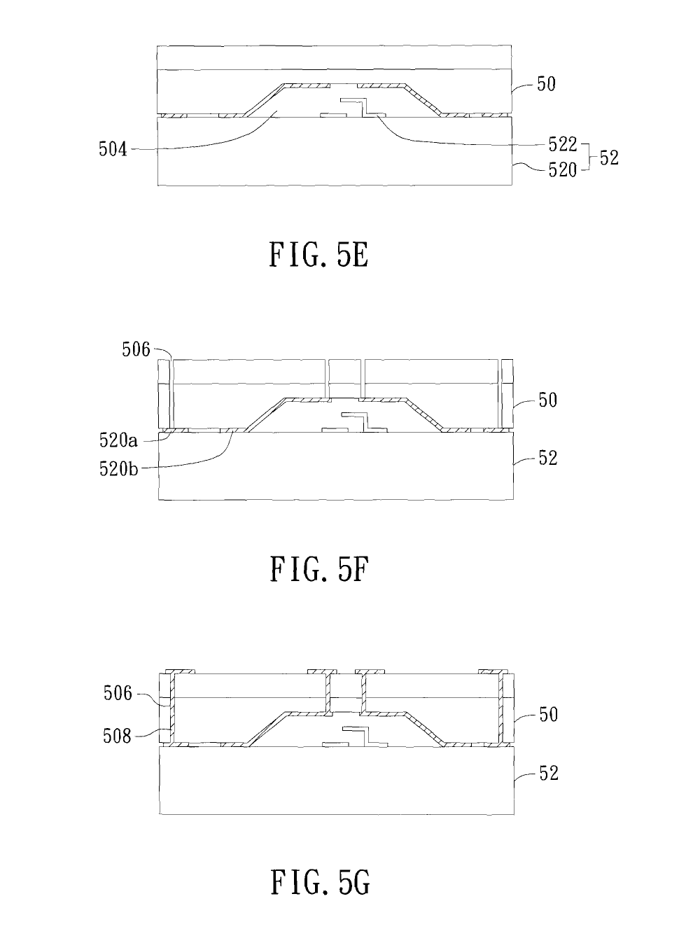

FIG. 5A to FIG. 5G are cross-sectional views showing a method for manufacturing a packaging structure for integration of microelectronics and MEMS devices by three-dimensional (3D) stacking according to still another embodiment of the present invention. The method comprises steps as follows.

In Step 1, an ASIC unit 50 is provided comprising a substrate 500 and a circuit layout 502 formed on a surface of the substrate 500, as shown in FIG. 5.

In Step 2, a thinning process using a polishing mechanism (not shown) is performed on the other surface of the first substrate 500 whereon there is no circuit layout, as shown in FIG. 5B.

In Step 3, a cavity 504 is formed (by, for example, wet etching) on the other surface of the first substrate 500 whereon there is no circuit layout, as shown in FIG. 5C.

In Step 4, a conductive portion 507, an electrical connection portion 520a and an electrical connection portion 520b are provided (by, for example, sputtering) in the cavity 504, as shown in FIG. 5D.

In Step 5, the ASIC unit 50 and the MEMS unit 52 comprising a substrate 520 and a micro sensor 522 disposed on the substrate 520 are stacked so that the micro sensor 522 is disposed in the cavity 504, as shown in FIG. 5E.

In Step 6, a plurality of through holes 506 are formed in the ASIC unit 50 so that the through holes 506 are electrically connected to the electrical connection portion 520a and the conductive portion 507, respectively, as shown in FIG. 5F.

In Step 7, the through holes 506 are filled with a conductive material 508 such as copper (Cu) so that the ASIC unit 50 and the MEMS unit 52 are electrically connected, as shown in FIG. 5G.

The foregoing steps can be modified as in FIG. 4 that only some of the through holes are filled with a conductive material, while the other through holes accommodate the micro sensors of the MEMS unit to interact with external signals. Such modifications are well known to any person with ordinary skills in the art and descriptions thereof are not presented.

Accordingly, the present invention discloses a packaging structure for integration of microelectronics and MEMS devices by three-dimensional (3D) stacking and a method for manufacturing the packaging structure, in which a cap is made for electrical connection and protection of the MEMS device and the ASIC unit and the MEMS unit can be completely integrated with higher integrity and lowered cost. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A packaging structure for integration of microelectronics and MEMS devices by 3D stacking, the packaging structure comprising:
an ASIC unit, comprising a first substrate and a circuit layout formed on a surface of the first substrate, wherein a cavity is formed on the other surface and at least a through hole is formed on the ASIC unit; and
a MEMS unit, comprising a second substrate and a micro sensor disposed on the second substrate;
wherein the micro sensor is disposed in the cavity and there is a conductive material filling the through hole so that the ASIC unit and the MEMS unit are electrically connected to each other when the ASIC unit is attached onto the MEMS unit.

2. The packaging structure as recited in claim 1, wherein the cavity comprises a conductive portion therein, the conductive portion being electrically connected to the through hole and the MEMS unit, respectively.

3. The packaging structure as recited in claim 1, wherein the through hole is electrically connected to the circuit layout on the surface of the first substrate.

4. The packaging structure as recited in claim 1, wherein the conductive material is a metal material.

5. The packaging structure as recited in claim 1, further comprising a plurality of ASIC units stacked on the circuit layout being electrically connected thereto.

6. A packaging structure for integration of microelectronics and MEMS devices by 3D stacking, the packaging structure comprising:
an ASIC unit, comprising a first substrate and a circuit layout formed on a surface of the first substrate, wherein a cavity is formed on the other surface and at least two through holes are formed on the ASIC unit; and
a MEMS unit, comprising a second substrate and a micro sensor disposed on the second substrate;
wherein the micro sensor is disposed in the cavity and there is a conductive material filling at least one of the through holes so that the ASIC unit and the MEMS unit are electrically connected to each other when the ASIC unit is attached onto the MEMS unit.

7. The packaging structure as recited in claim 6, wherein the cavity comprises a conductive portion therein, the conductive portion being electrically connected to at least one of the through holes and the MEMS unit, respectively.

8. The packaging structure as recited in claim 6, wherein at least one of the through holes is electrically connected to the circuit layout on the surface of the first substrate.

9. The packaging structure as recited in claim 6, wherein the conductive material is a metal material.

10. The packaging structure as recited in claim 6, further comprising a plurality of ASIC units stacked on the circuit layout being electrically connected thereto.

11. A method for manufacturing a packaging structure for integration of microelectronics and MEMS devices by 3D stacking, the method comprising steps of:
(a) providing an ASIC unit and a MEMS unit, the ASIC unit comprising a first substrate and a circuit layout formed on a surface of the first substrate and the MEMS unit comprising a second substrate and a micro sensor disposed on the second substrate;
(b) performing a thinning process on the other surface of the first substrate;
(c) forming a cavity on the other surface of the first substrate, wherein the micro sensor is disposed in the cavity;
(d) providing a conductive portion in the cavity, the conductive portion being electrically connected to the MEMS unit;
(e) stacking the ASIC unit and MEMS unit so that the micro sensor is disposed in the cavity;
(f) forming at least a through hole so that the through hole is electrically connected to the circuit layout and the conductive portion, respectively; and
(g) filling the through hole with a conductive material so that the circuit layout and the conductive portion are electrically connected.

12. The packaging structure as recited in claim 11, wherein the conductive material is a metal material.
